(19) United States
(12) Patent Application Publication
(10) Pub. No.: US 2025/0068064 A1
(43) Pub. Date: Feb. 27, 2025

(54) ANTI-SPACER BASED SELF-ALIGNED HIGH ORDER PATTERNING

(71) Applicant: Geminatio, Inc., Schenectady, NY (US)

(72) Inventors: Brennan Peterson, Longmont, CO (US); Phillip D. Hustad, Longmont, CO (US)

(73) Assignee: Geminatio, Inc., Schenectady, NY (US)

(21) Appl. No.: 18/686,819

(22) PCT Filed: Aug. 25, 2022
(86) PCT No.: PCT/US2022/041550

§ 371 Date: Feb. 26, 2024

Related U.S. Application Data
(60) Provisional application No. 63/236,855, filed on Aug. 25, 2021.

(51) Int. Cl. G03F 7/00; G03F 7/32; G03F 7/38; G03F 7/42; H01L 21/027

(52) U.S. Cl. CPC G03F 7/0035; G03F 7/32; G03F 7/38; G03F 7/422; H01L 21/0274

(57) ABSTRACT

A method of microfabrication includes providing a first relief pattern on a substrate, forming carbon—containing sidewall spacers—in the first relief pattern, removing the first relief pattern, and coating the carbon—containing sidewall spacers with a solubility—shifting agent. Then, the method includes depositing a first polymer fill on the carbon—containing sidewall spacers, diffusing the solubility—shifting agent a predetermined distance into the first polymer fill to provide a solubility—shifted region of the first polymer fill, wherein the solubility—shifted region of the first polymer fill borders the carbon—containing sidewall spacers, and developing the first polymer fill such that the solubility—shifted region is dissolved providing trenches between the carbon—containing sidewall spacers and the first polymer fill where a portion of the substrate is exposed.

### BACKGROUND

Microfabrication of semiconductor devices includes various steps such as film deposition, pattern formation, and pattern transfer. Materials and films are deposited on a substrate by spin coating, vapor deposition, and other deposition processes. Pattern formation is typically performed by exposing a photo-sensitive film, known as a resist, to a pattern of actinic radiation and subsequently developing the resist to form a relief pattern. The relief pattern then acts as an etch mask, which, when one or more etching processes are applied to the substrate, cover portions of the substrate that are not to be etched.

Multi-patterning is a term that describes using more than one lithography step to create a final pattern. Multi-pattering, in different forms, enables the production of advanced semiconductor devices. Patterning typically includes two fundamental steps. The first step includes using lithography to create a pattern using mask-based exposure of light followed by development of soluble regions. The second step includes transferring the pattern into an underlying material by directional or anisotropic etching. These two steps together may be referred to as patterning a device.

### SUMMARY

This summary is provided to introduce a selection of concepts that are further described below in the detailed description. This summary is not intended to identify key or essential features of the claimed subject matter, nor is it intended to be used as an aid in limiting the scope of the claimed subject matter.

In one aspect, embodiments disclosed herein relate to a method of microfabrication including providing a first relief pattern on a substrate, wherein the first relief pattern includes a first resist, forming carbon-containing sidewall spacers on the first relief pattern, removing the first relief pattern, and coating the carbon-containing sidewall spacers with a solubility-shifting agent. Then, the method includes depositing a first polymer fill on the carbon-containing sidewall spacers such that the first polymer fill is in contact with the carbon-containing sidewall spacers, diffusing the solubility-shifting agent a predetermined distance into the first polymer fill to provide a solubility-shifted region of the first polymer fill, wherein the solubility-shifted region of the first polymer fill borders the carbon-containing sidewall spacers, and developing the first polymer fill such that the solubility-shifted region is dissolved providing trenches between the carbon-containing sidewall spacers and the first polymer fill where a portion of the substrate is exposed.

In another aspect, embodiments herein relate to a method of microfabrication including providing a layer of amorphous carbon on a substrate, providing a first relief pattern on the layer of amorphous carbon, wherein the first relief pattern comprises a first resist, applying an inorganic spacer to the first relief pattern, and transferring a pattern defined by the first relief pattern and the inorganic spacer into the underlying layer of amorphous carbon to provide an etched layer of amorphous carbon. Then, the method includes removing the first relief pattern and the inorganic spacer, coating the etched layer of amorphous with a solubility-shifting agent, depositing a first polymer fill on the etched layer of amorphous carbon, diffusing the solubility-shifting agent a predetermined distance into the first polymer fill to provide a solubility-shifted region of the first polymer fill, wherein the solubility-shifted region of the first polymer fill borders the etched layer of amorphous carbon, and developing the first polymer fill such that the solubility-shifted region is dissolved providing trenches between the etched layer of amorphous carbon and the first polymer fill where a portion of the substrate is exposed.

Other aspects and advantages of the claimed subject matter will be apparent from the following description and the appended claims.

### BRIEF DESCRIPTION OF DRAWINGS

FIG. 1 is a schematic depiction of a conventional patterning flow in accordance with one or more embodiments of the present disclosure.

FIG. 2 is a block-flow diagram of a method in accordance with one or more embodiments of the present disclosure.

FIGS. 3A-G are schematic illustrations of coated substrates at respective points of a method in accordance with one or more embodiments of the present disclosure.

### DETAILED DESCRIPTION

High density patterning is a desirable goal that has long inspired the development of new methods and systems for microfabrication of semiconductor substrates. Some of the leading technologies for high density patterning are pitch multiplication techniques. These techniques have different tradeoffs. Some pitch multiplication techniques offer constant line thickness, while others offer consistent spacing, and still others are flexible in implementation.

For higher order spacer patterning, it is important to be able to repeat the steps of double patterning. Conventionally this is done with sidewall spacers formed on mandrels using vapor deposition and etch chambers.

The present disclosure generally relates to a method of multi-patterning a semiconductor substrate. Herein, the terms “semiconductor substrate” and “substrate” are used interchangeably, and may be any semiconductor material including, but not limited to, semiconductor wafers, semiconductor material layers, and combinations thereof. In one or more embodiments, the method includes using track-based patterning flows to form anti-spacers (i.e., narrow trenches defined by chemical diffusion) instead of spacers. In performing a patterning flow on a coater-developer tool (e.g., a track-based flow), a higher throughput and decreased cost may be achieved according to the method disclosed herein. Additionally, the method may include using resist-clearing based spacer technologies to extend quadruple and higher patterning capability, thus providing complex substrates at a lower cost.

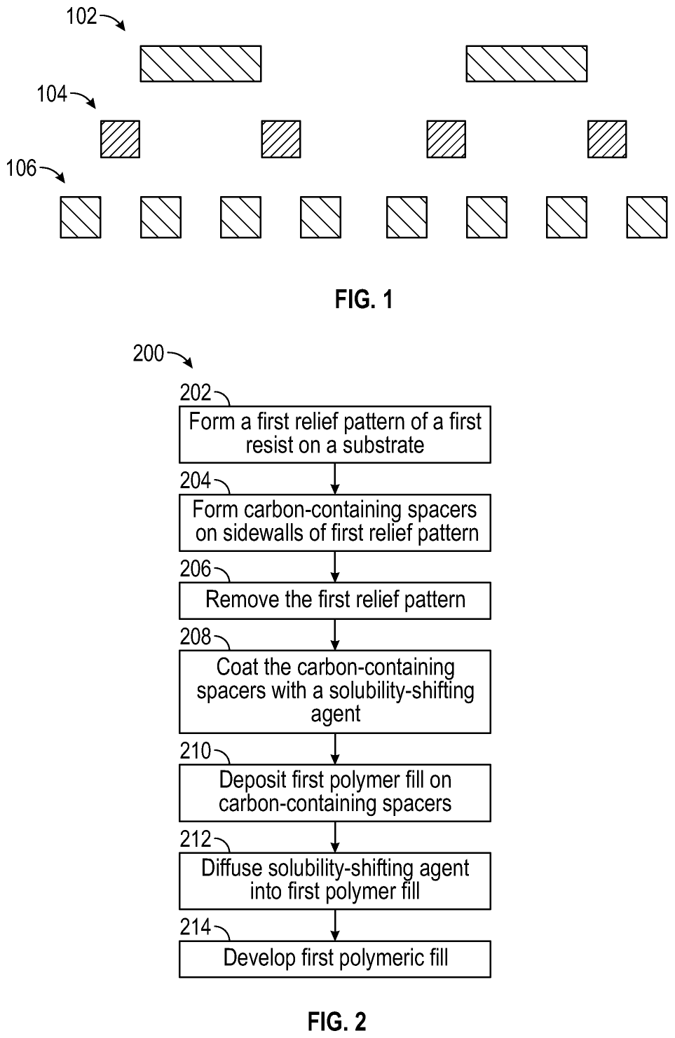

A conventional pattern quadrupling flow using spacer formation is detailed below. First, an initial pattern with a width of 3 units and a pitch of 8 units may be placed on a substrate. Spacers may then be formed on the initial pattern which may include lines or mandrels. Spacer deposition, typically by conformal vapor deposition, may be one unit. After spacer open etch, a first set of sidewall spacers may be formed on mandrels of one unit in width. The initial pattern may then be removed (e.g., the mandrels may be exhumed). Then, a second set of sidewall spacers of one unit width may be formed on the first sidewall spacers. Thus, the first set of sidewall spacers become the new mandrels for sidewall spacer formation. The resulting pattern is a pitch of 2× (a 4× reduction) and a width of 1× unit. Such patterning flow is shown in FIG. 1. In FIG. 1, 102 represents the initial mandrels, 104 is the first set of sidewall spacers to be used as second mandrels, and 106 is the second set of sidewall spacers for transfer into an underlying layer.

Additionally, in conventional spacer quadrupling flows, a final pattern having a critical dimension (CD) or width of 1×/2, may be prepared from an intermediate pattern having width of 3×/2, and an initial pattern having a width of 5×/2. A wide range of conditions in conventional quadrupling flows may allow a variety of different patterns. In the context of the negative spacer process, a final pitch of about 20 nm and a width of 10 nm implies an initial target width of about 25 nm, and pitch of about 80 nm, by way of one example.

A method, 200, for pitch multiplication in accordance with one or more embodiments is shown in, and discussed with reference to, FIG. 2. Generally, method 200, includes an anti-spacer on spacer on resist flow. Initially, a substrate is received. Then, at block 202, a first relief pattern of a first resist is provided on the substrate, via execution of an initial photolithography step. The first relief pattern, for example, can have a target pitch of 8× and a target CD of 3×. Then, at block 204, carbon-containing spacers are formed on a sidewall of the first relief pattern, with these spacers having a width target of 1.5×. At block 206, the first resist is removed. Then, at block 208, a solubility-shifting agent such as an acid is deposited on the carbon-containing sidewall spacers. At block 210, the substrate may be spin coated with a first polymer fill. The first polymer fill may be an acid soluble resist or polymer. The solubility-shifting agent from the spacer is then diffused into the first polymer fill at block 212, activated, and solubility-shifted regions of the first polymer fill are developed at block 214.

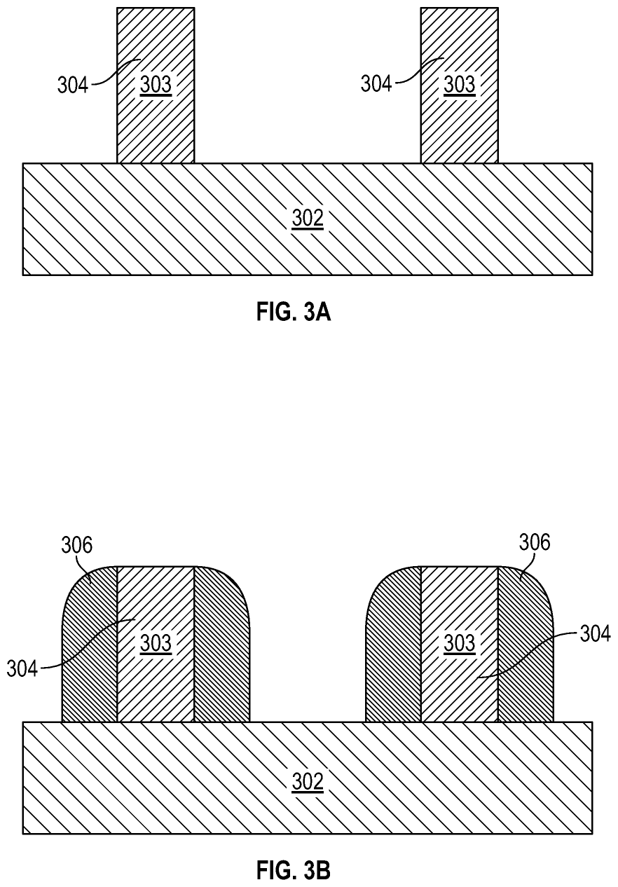

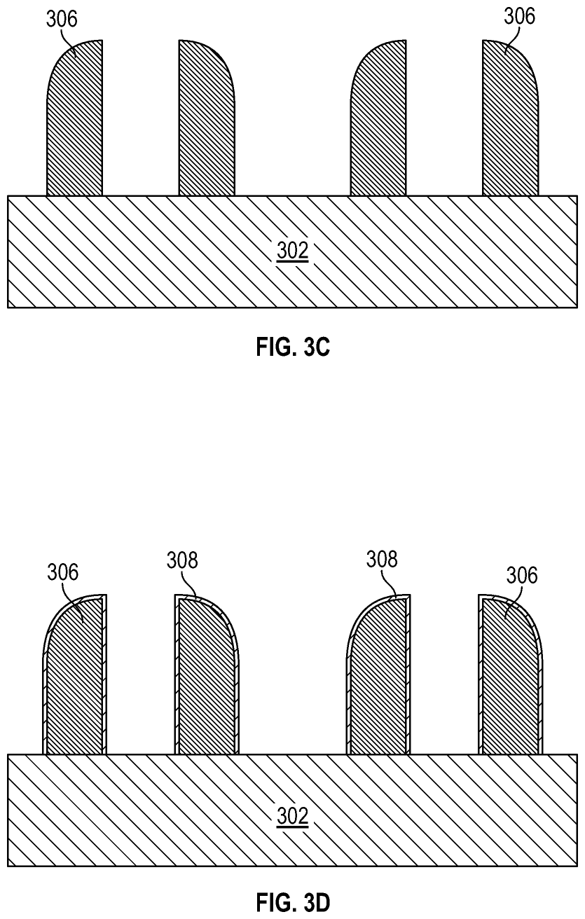

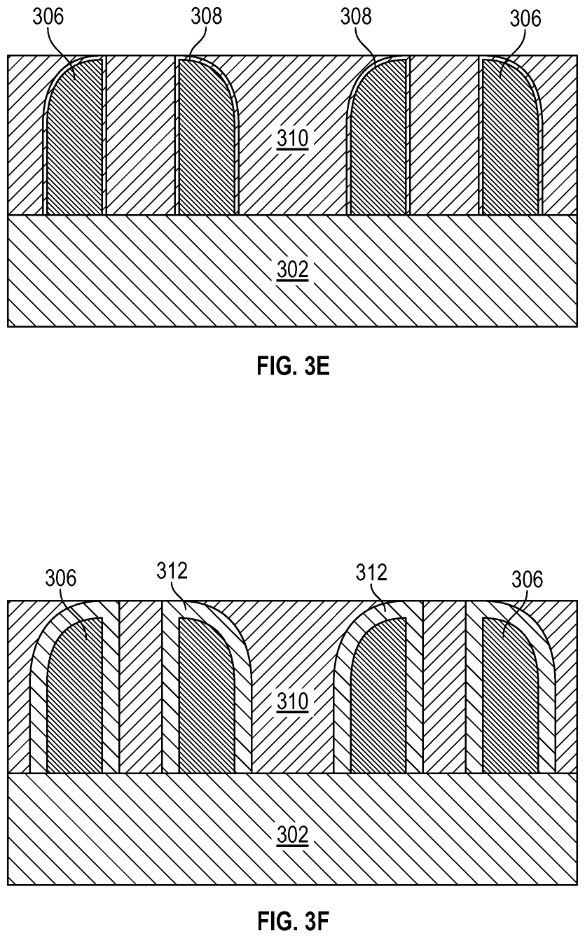

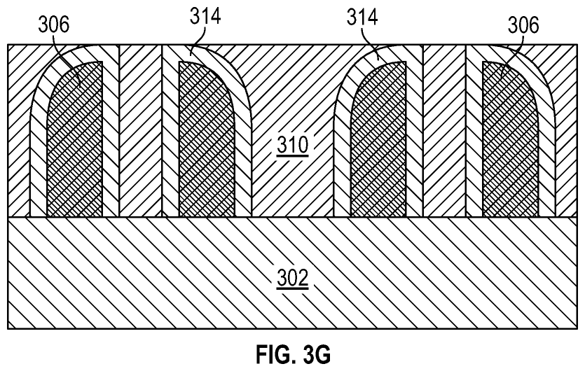

Schematic depictions of a coated substrate at various points during the method described above are shown in FIGS. 3A-3G. Herein “a coated substrate” refers to a substrate that is coated with one or more layers, such as a first resist layer and a second resist layer. FIG. 3A shows a substrate including a first relief pattern. FIG. 3B shows a substrate including a first relief pattern and carbon-containing spacers formed on the sidewall of the first relief pattern. In FIG. 3C, the first relief pattern is removed from the substrate. FIG. 3D shows a substrate including the carbon-containing spacers coated with a solubility-shifting agent. In FIG. 3E, a first polymer fill is layered over the substrate and the carbon-containing spacers. FIG. 3F shows a coated substrate after the solubility-shifting agent has been diffused into the first polymer fill. Finally, FIG. 3G shows a coated substrate after the second resist has been developed, such that portions of the substrate are exposed and able to be etched. The method of FIG. 2 and coated substrates shown in FIGS. 3A-3G are discussed in detail below.

At block 202 of method 200, a first relief pattern is provided. FIG. 3A shows an example of a first relief pattern 304 on a substrate 302. A shown in FIG. 3A, the first relief pattern may include features separated by gaps. Portions of the substrate may be exposed by the presence of the gaps of the first relief pattern. The features of the first relief pattern may be made of a first photoresist 303. Generally, a photoresist is a chemically amplified photosensitive composition that comprises a polymer, a photoacid generator, and a solvent. In one or more embodiments, the first resist includes a polymer. The polymer may be any standard polymer typically used in resist material and may particularly be a polymer having acid-labile groups. For example, the polymer may be a polymer made from monomers including vinyl aromatic monomers such as styrene and p-hydroxystyrene, acrylate, methacrylate, norbornene, and combinations thereof. Monomers that include reactive functional groups may be present in the polymer in a protected form. For example, the —OH group of p-hydroxystyrene may be protected with a tert-butyloxycarbonyl protecting group. Such protecting group may alter the reactivity and solubility of the polymer included in the first resist. As will be appreciated by one having ordinary skill in the art, various protecting groups may be used for this reason.

Acid-labile groups include, for example: tertiary alkyl ester groups, secondary or tertiary aryl ester groups, secondary or tertiary ester groups having a combination of alkyl and aryl groups, tertiary alkoxy groups, acetal groups, or ketal groups. Acid-labile groups are also commonly referred to in the art as “acid-decomposable groups”, “acid-cleavable groups,” “acid-cleavable protecting groups,” “acid-labile protecting groups,” “acid-leaving groups,” and “acid-sensitive groups.”

The acid-labile group which, on decomposition, forms a carboxylic acid on the polymer is preferably a tertiary ester group of the formula —C(O)OC(R¹)₃ or an acetal group of the formula —C(O)OC(R²)₂OR³, wherein: R¹ is each independently linear C₁₋₂₀ alkyl, branched C₃₋₂₀ alkyl, monocyclic or polycyclic C₃₋₂₀ cycloalkyl, linear C₂₋₂₀ alkenyl, branched C₃₋₂₀ alkenyl, monocyclic or polycyclic C₃₋₂₀ cycloalkenyl, monocyclic or polycyclic C₆₋₂₀ aryl, or monocyclic or polycyclic C₂₋₂₀ heteroaryl, preferably linear C₁₋₆ alkyl, branched C₃₋₆ alkyl, or monocyclic or polycyclic C₃₋₁₀ to cycloalkyl, each of which is substituted or unsubstituted, each R¹ optionally including as part of its structure one or more groups chosen from —O—, —C(O)—, —C(O)—O— or —S—, and any two R¹ groups together optionally forming a ring; R² is independently hydrogen, fluorine, linear C₁₋₂₀ alkyl, branched C₃₋₂₀ alkyl, monocyclic or polycyclic C₃₋₂₀ cycloalkyl, linear C₂₋₂₀ alkenyl, branched C₃₋₂₀ alkenyl, monocyclic or polycyclic C₃₋₂₀ cycloalkenyl, monocyclic or polycyclic C₆₋₂₀ aryl, or monocyclic or polycyclic C₂₋₂₀ heteroaryl, preferably hydrogen, linear C₁₋₆ alkyl, branched C₃₋₆ alkyl, or monocyclic or polycyclic C₃₋₁₀ cycloalkyl, each of which is substituted or unsubstituted, each R² optionally including as part of its structure one or more groups chosen from —O—, —C(O)—, —C(O)—O—, or —S—, and the R² groups together optionally forming a ring; and R³ is linear C₁₋₂₀ alkyl, branched C₃₋₂₀ alkyl, monocyclic or polycyclic C₃₋₂₀ cycloalkyl, linear C₂₋₂₀ alkenyl, branched C₃₋₂₀ alkenyl, monocyclic or polycyclic C₃₋₂₀ cycloalkenyl, monocyclic or polycyclic C₆₋₂₀ aryl, or monocyclic or polycyclic C₂₋₂₀ heteroaryl, preferably linear C₁₋₆ alkyl, branched C₃₋₆ alkyl, or monocyclic or polycyclic C₃₋₁₀ cycloalkyl, each of which is substituted or unsubstituted, R³ optionally including as part of its structure one or more groups chosen from —O—, —C(O)—, —C(O)—O—, or —S—, and one R² together with R³ optionally forming a ring. Such monomer is typically a vinyl aromatic, (meth)acrylate, or norbornyl monomer. The total content of polymerized units comprising an acid-decomposable group which forms a carboxylic acid group on the polymer is typically from 10 to 100 mole %, more typically from 10 to 90 mole % or from 30 to 70 mole %, based on total polymerized units of the polymer.

The polymer can further include as polymerized a monomer comprising an acid-labile group, the decomposition of which group forms an alcohol group or a fluoroalcohol group on the polymer. Suitable such groups include, for example, an acetal group of the formula —COC(R²)₂OR³—, or a carbonate ester group of the formula —OC(O)O—, wherein R is as defined above. Such monomer is typically a vinyl aromatic, (meth)acrylate, or norbornyl monomer. If present in the polymer, the total content of polymerized units comprising an acid-decomposable group, the decomposition of which group forms an alcohol group or a fluoroalcohol group on the polymer, is typically from 10 to 90 mole %, more typically from 30 to 70 mole %, based on total polymerized units of the polymer.

In embodiments in which the first resist is a photoresist, the first resist includes a photoacid generator. The photoacid generator is a compound capable of generating an acid upon irradiation with actinic rays or radiation. The photoacid generator may be selected from known compounds capable of generating an acid upon irradiation with actinic rays or radiation which are used for a photoinitiator for cationic photopolymerization, a photoinitiator for radical photopolymerization, a photodecoloring agent for dyes, a photodiscoloring agent, a microresist, or the like, and a mixture thereof can be used. Examples of the photoacid generator include a diazonium salt, a phosphonium salt, a sulfonium salt, an iodonium salt, imidosulfonate, oxime sulfonate, diazodisulfone, disulfone, and o-nitrobenzyl sulfonate.

Suitable photoacids include onium salts, for example, triphenylsulfonium trifhioromethanesulfonate, (p-tert-butoxyphenyl)diphenylsulfonium trifhioromethanesulfonate, tris(p-tert-butoxyphenyl)sulfonium trifluoromethanesulfonate, triphenylsulfonium p-toluenesulfonate; di-t-butyphenyliodonium perfluorobutanesulfonate, and di-t-butyphenyliodonium camphorsulfonate. Non-ionic sulfonates and sulfonyl compounds are also known to function as photoacid generators, e.g., nitrobenzyl derivatives, for example, 2-nitrobenzyl-p-toluenesulfonate, 2,6-dinitrobenzyl-p-toluenesulfonate, and 2,4-dinitrobenzyl-p-toluenesulfonate; sulfonic acid esters, for example, 1,2,3-tris(methanesulfonyloxy)benzene, 1,2,3-tris(trifluoromethanesulfonyloxy)benzene, and 1,2,3-tris(p-toluenesulfonyloxy)benzene; diazomethane derivatives, for example, bis(benzenesulfonyl)diazomethane, bis(p-toluenesulfonyl)diazomethane; glyoxime derivatives, for example, bis-O-(p-toluenesulfonyl)-α-dimethylglyoxime, and bis-O-(n-butanesulfonyl)-α-dimethylglyoxime; sulfonic acid ester derivatives of an N-hydroxyimide compound, for example, N-hydroxysuccinimide methanesulfonic acid ester, N-hydroxysuccinimide trifluoromethanesulfonic acid ester; and halogen-containing triazine compounds, for example, 2-(4-methoxyphenyl)-4,6-bis(trichloromethyl)-1,3,5-triazine, and 2-(4-methoxynaphthyl)-4,6-bis(trichloromethyl)-1,3,5-triazine. Suitable non-polymerized photoacid generators are further described in U.S. Pat. No. 8,431,325 to Hashimoto et al. in column 37, lines 11-47 and columns 41-91. Other suitable sulfonate PAGs include sulfonated esters and sulfonyloxy ketones, nitrobenzyl esters, s-triazine derivatives, benzoin tosylate, t-butylphenyl α-(p-toluenesulfonyloxy)-acetate, and t-butyl α-(p-toluenesulfonyloxy)-acetate; as described in U.S. Pat. Nos. 4,189,323 and 8,431,325. PAGs that are onium salts typically comprise an anion having a sulfonate group or a non-sulfonate type group, such as a sulfonamidate group, a sulfonimidate group, a methide group, or a borate group.

The resist composition may optionally comprise a plurality of PAGs. The plural PAGs may be polymeric, non-polymeric, or may include both polymeric and non-polymeric PAGs. Preferably, each of the plurality of PAGs is non-polymeric. Preferably, when a plurality of PAGs are used, a first PAG comprises a sulfonate group on the anion and a second PAG comprises an anion that is free of sulfonate groups, such anion containing for example, a sulfonamidate group, a sulfonimidate group, a methide group, or a borate group such as described above.

The first relief pattern may be formed by layering the first resist onto a substrate and the developing the first resist. The first resist may be developed according to procedures known in the art, e.g., exposure to actinic radiation followed by rinsing with a first resist developer. In order to impart a shape, or relief pattern, in the developed resist, a mask may be used to block a portion of the resist from the actinic radiation. After the actinic radiation is applied, the unexposed portion of the resist may have a different solubility than the exposed portion of the resist. Subsequent rinsing with the first resist developer will dissolve either the unexposed portion or the exposed portion. A relief pattern provided when the unexposed portion of the resist remains after rinsing with a developer is a positive tone developed resist. In contrast, a relief pattern provided when the exposed portion of the resist remains after rinsing with a developer is a negative resist or a negative tone developed resist.

In some embodiments, the first resist is a positive tone developed (PTD) resist. In such embodiments, the first relief pattern may include a polymer made from the above described monomers, wherein any monomers including a reactive functional group are protected. As such, a PTD first resist may be organic soluble, and thus the relief pattern may be provided by rinsing with a first resist developer that is basic. Suitable basic first resist developers include quaternary ammonium hydroxides, such as tetramethylammonium hydroxide (TMAH).

In other embodiments, the first resist is a negative resist. In such embodiments, the first relief pattern may include a polymer made from the above described monomers, wherein any monomers including a reactive functional group are not protected. Exposure to actinic radiation results in crosslinking of the polymer in areas of exposure, rendering the polymer insoluble to developers. The unexposed and thus uncrosslinked areas can then be removed using an appropriate developer to form the relief pattern.

In other embodiments, the first resist is a negative tone developed (NTD) resist. Similar to PTD resists, NTD resists may include a polymer made from the above described monomers, wherein any monomers including a reactive functional group are protected. As such, a NTD first resist may be organic soluble, but instead of developing the exposed areas with a first resist developer that is basic, the first relief pattern may be provided by rinsing the first resist with a first resist developer including an organic solvent. Suitable organic solvents that may be used as a first resist developer include n-butyl acetate (NBA) and 2-heptanone. The tone of the resist (i.e., PTD vs. NTD) may influence the subsequent chemistry applied to the first relief pattern.

In other embodiments, the first resist optionally contains other additives, wherein other additives include at least one of a resin having at least either a fluorine atom or a silicon atom, a basic compound, a surfactant, an onium carboxylate, dye, a plasticizer, a photo sensitizer, a light absorbent, an alkali-soluble resin, a dissolution inhibitor, and a compound for accelerating dissolution in a developer.

As previously described, the first relief pattern may include features separated by gaps. In one or more embodiments, the features of the first relief pattern may have a thickness of about 300 Å to about 3000 Å. The gaps separating the features may leave portions of the substrate exposed.

In some embodiments, the first relief pattern is stabilized prior to coating with the solubility-shifting agent. Various resist stabilization techniques, also known as freeze processes, have been proposed such as ion implantation, UV curing, thermal hardening, thermal curing and chemical curing. Techniques are described, for example, in US2008/0063985A1, US 2008/0199814A1 and US 2010/0330503A1.

At block 204 of method 200, carbon-containing spacers are formed on a sidewall of the first relief pattern. In one or more embodiments, every sidewall of the first relief pattern is coated with a carbon-containing spacer. FIG. 3B shows a coated substrate in which carbon-containing-spacers are coated on the sidewalls of a first relief pattern. In FIG. 3B, a substrate 302 includes a first relief pattern 304. On each side of the features of the first relief pattern 304, a carbon-containing spacer 306 is formed. A carbon-containing spacer may be any suitable carbon-containing spacer commonly used in the art. For example, suitable carbon-containing spacers may include carbon-based material such as amorphous carbons, a combination of amorphous carbon and hydrogen (hydrogenated amorphous carbon film). One exemplary amorphous carbon film may be a strippable Advanced Patterning Film™ (APF) material commercially available from Applied Materials, Inc. of Santa Clara, Calif. The amorphous carbon layer may be deposited by any suitable deposition techniques such as chemical vapor deposition (CVD), plasma enhanced chemical vapor deposition (PECVD), atomic layer deposition (ALD), spin-coating, or casting. The amorphous carbon layer may be deposited by flowing, among others, a hydrocarbon source, such as a gas-phase hydrocarbon or a liquid-phase hydrocarbon that has been entrained in a carrier gas and a plasma-initiating gas into a PECVD chamber. The hydrocarbon source may be a mixture of one or more hydrocarbon compounds. The hydrocarbon compounds may be partially or completely doped derivatives of hydrocarbon compounds, including nitrogen-, fluorine-, oxygen-, hydroxyl group-, and boron-containing derivatives of hydrocarbon compounds. Hydrocarbon compounds or derivatives thereof that may be included in the hydrocarbon source may be described by the formula CxHy, where x has a range of between 1 and 10 and y has a range of between 2 and 30. Suitable hydrocarbon compounds may include, but are not limited to, acetylene (C2H2), ethane (C2H6), propylene (C3H6), propyne (C3H4), propane (C3H8), butane (C4H10), butylene (C4H8), butyne (C4H6), vinylacetylene, phenylacetylene (C8H6), benzene, styrene, toluene, xylene, ethylbenzene, acetophenone, methyl benzoate, phenyl acetate, phenol, cresol, furan, alpha-terpinene, cymene, 1,1,3,3,-tetramethylbutylbenzene, t-butylether, t-butylethylene, methyl-methacrylate, and t-butylfurfurylether, compounds having the formula C3H2 and C5H4, monofluorobenzene, difluorobenzenes, tetrafluorobenzenes, hexafluorobenzene, and the like. Additional suitable hydrocarbons may include ethylene, pentene, butadiene, isoprene, pentadiene, hexadiene, monofluoroethylene, difluoroethylenes, trifluoroethylene, tetrafluoroethylene, monochloroethylene, dichloroethylenes, trichloroethylene, tetrachloroethylene, and the like. Process parameters may be controlled to produce an amorphous carbon layer having a thickness of about 10 Å to about 1,000 Å depending on the desired final dimensions.

Then, at block 206, method 200 includes removing the first resist. FIG. 3C shows a coated substrate in which the first resist has been removed, such that the substrate 302 only includes the carbon-containing spacers 306. The first resist may be removed according to methods known in the art, such as, for example, using an anisotropic etch or other suitable wet stripping process, The etchants are chosen to be selective for the resist material relative to the carbon spacer.

At block 208, the carbon-containing spacers are coated with a solubility-shifting agent. A coated substrate in accordance with block 208 is shown in FIG. 3D. The solubility-shifting agent 308 is shown as a coating over the carbon-containing spacers 306. The thickness of the solubility-shifting agent coating is not particularly limited and may be altered based on the desired width of the final pattern. The solubility-shifting agent may be a material that is absorbed into the carbon-containing spacers via a bake, and in some instances herein may be referred to as an “absorbed material.” The process of absorbing, or diffusing, the solubility-shifting agent into the carbon-containing spacers is described in detailed below.

Generally, the solubility-shifting agent may be a suitable chemical that activates with light or heat. For example, when the first polymer fill includes a chemically amplified resist, the solubility-shifting agent may include an acid or acid generator. The acid or generated acid in the case of a TAG should be sufficient with heat to cause cleavage of the bonds of acid-decomposable groups of the polymer in a surface region of the first resist pattern to cause increased solubility of the first resist polymer in a specific developer to be applied. The acid or TAG is typically present in the composition in an amount of from about 0.01 to 20 wt % based on the total solids of the trimming composition.

Preferable acids are organic acids including non-aromatic acids and aromatic acids, each of which can optionally have fluorine substitution. Suitable organic acids include, for example: carboxylic acids such as alkanoic acids, including formic acid, acetic acid, propionic acid, butyric acid, dichloroacetic acid, trichloroacetic acid, perfluoroacetic acid, perfluorooctanoic acid, oxalic acid malonic acid and succinic acid; hydroxyalkanoic acids, such as citric acid; aromatic carboxylic acids such as benzoic acid, fluorobenzoic acid, hydroxybenzoic acid and naphthoic acid; organic phosphorus acids such as dimethylphosphoric acid and dimethylphosphinic acid; and sulfonic acids such as optionally fluorinated alkylsulfonic acids including methanesulfonic acid, trifluoromethanesulfonic acid, ethanesulfonic acid, 1-butanesulfonic acid, 1-perfluorobutanesulfonic acid, 1,1,2,2-tetrafluorobutane-1-sulfonic acid, 1,1,2,2-tetrafluoro-4-hydroxybutane-1-sulfonic acid, 1-pentanesulfonic acid, 1-hexanesulfonic acid, and 1-heptanesulfonic acid.

Exemplary aromatic acids that are free of fluorine include wherein aromatic acids of the general formula (I):

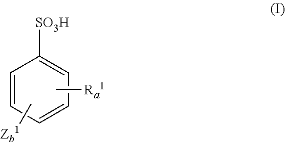

wherein: R1 independently represents a substituted or unsubstituted C1-C20 alkyl group, a substituted or unsubstituted C5-C20 aryl group or a combination thereof, optionally containing one or more group chosen from carbonyl, carbonyloxy, sulfonamido, ether, thioether, a substituted or unsubstituted alkylene group, or a combination thereof; Z1 independently represents a group chosen from carboxyl, hydroxy, nitro, cyano, C1 to C5 alkoxy, formyl and sulfonic acid; a and b are independently an integer from 0 to 5; and a +b is 5 or less.

Exemplary aromatic acids may be of the general formula (II):

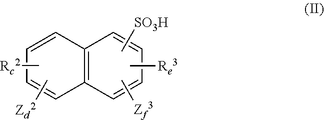

wherein: R2 and R3 each independently represents a substituted or unsubstituted C1-C20 alkyl group, a substituted or unsubstituted C5-C16 aryl group or a combination thereof, optionally containing one or more group chosen from carbonyl, carbonyloxy, sulfonamido, ether, thioether, a substituted or unsubstituted alkylene group, or a combination thereof; Z2 and Z3 each independently represents a group chosen from carboxyl, hydroxy, nitro, cyano, C1 to C5 alkoxy, formyl and sulfonic acid; c and d are independently an integer from 0 to 4; c+d is 4 or less; e and f are independently an integer from 0 to 3; and e+f is 3 or less.

Additional aromatic acids that may be included in the solubility-shifting agent include those the general formula (III) or (IV):

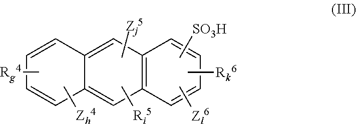

wherein: R4, R5 and R6 each independently represents a substituted or unsubstituted C1-C20 alkyl group, a substituted or unsubstituted C5-C12 aryl group or a combination thereof, optionally containing one or more group chosen from carbonyl, carbonyloxy, sulfonamido, ether, thioether, a substituted or unsubstituted alkylene group, or a combination thereof; Z4, Z5 and Z6 each independently represents a group chosen from carboxyl, hydroxy, nitro, cyano, C1 to C5 alkoxy, formyl and sulfonic acid; g and h are independently an integer from 0 to 4; g+h is 4 or less; i and j are independently an integer from 0 to 2; i+j is 2 or less; k and l are independently an integer from 0 to 3; and k+1 is 3 or less;

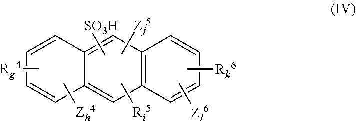

wherein: R4, R5 and R6 each independently represents a substituted or unsubstituted C1-C20 alkyl group, a substituted or unsubstituted C5-C12 aryl group or a combination thereof, optionally containing one or more group chosen from carbonyl, carbonyloxy, sulfonamido, ether, thioether, a substituted or unsubstituted alkylene group, or a combination thereof; Z4, Z5 and Z6 each independently represents a group chosen from carboxyl, hydroxy, nitro, cyano, C1 to C5 alkoxy, formyl and sulfonic acid; g and h are independently an integer from 0 to 4; g+h is 4 or less; i and j are independently an integer from 0 to 1; i+j is 1 or less; k and 1 are independently an integer from 0 to 4; and k+1 is 4 or less.

Suitable aromatic acids may alternatively be of the general formula (V):

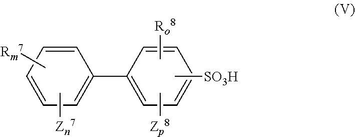

wherein: R7 and R8 each independently represents a substituted or unsubstituted C1-C20 alkyl group, a substituted or unsubstituted C5-C14 aryl group or a combination thereof, optionally containing one or more group chosen from carboxyl, carbonyl, carbonyloxy, sulfonamido, ether, thioether, a substituted or unsubstituted alkylene group, or a combination thereof; Z7 and Z8 each independently represents a group chosen from hydroxy, nitro, cyano, C1 to C5 alkoxy, formyl and sulfonic acid; m and n are independently an integer from 0 to 5; m+n is 5 or less; o and p are independently an integer from 0 to 4; and o+p is 4 or less.

Additionally, exemplary aromatic acids may have the general formula (VI):

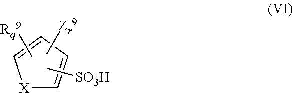

wherein: X is O or S; R9 independently represents a substituted or unsubstituted C1-C20 alkyl group, a substituted or unsubstituted C5-C20 aryl group or a combination thereof, optionally containing one or more group chosen from carbonyl, carbonyloxy, sulfonamido, ether, thioether, a substituted or unsubstituted alkylene group, or a combination thereof; Z9 independently represents a group chosen from carboxyl, hydroxy, nitro, cyano, C1 to C5 alkoxy, formyl and sulfonic acid; q and r are independently an integer from 0 to 3; and q+r is 3 or less.

In one or more embodiments, the acid is a free acid having fluorine substitution. Suitable free acids having fluorine substitution may be aromatic or nonaromatic. For example, free acid having fluorine substitution that may be used as solubility-shifting agent include, but are not limited to the following:

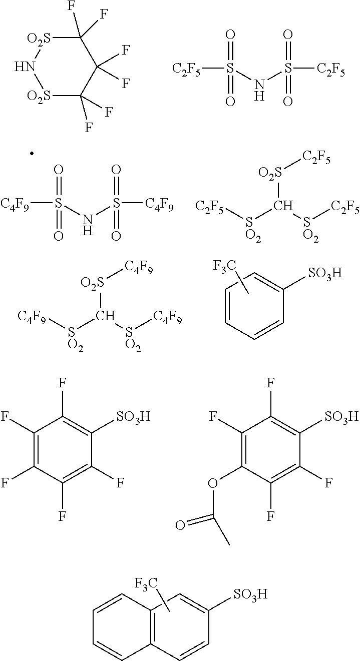

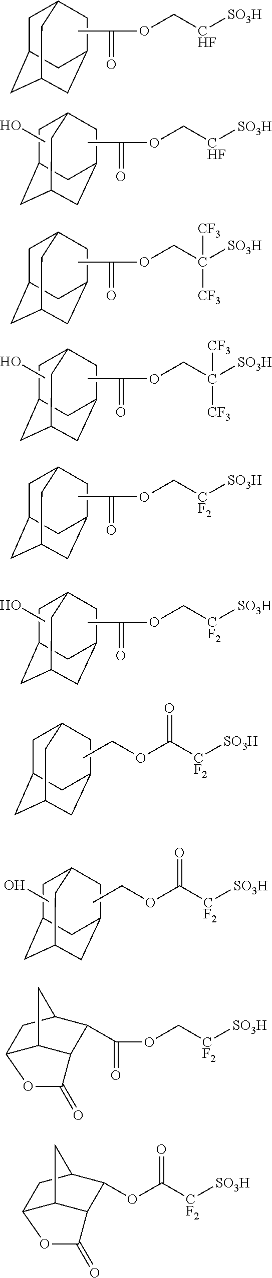

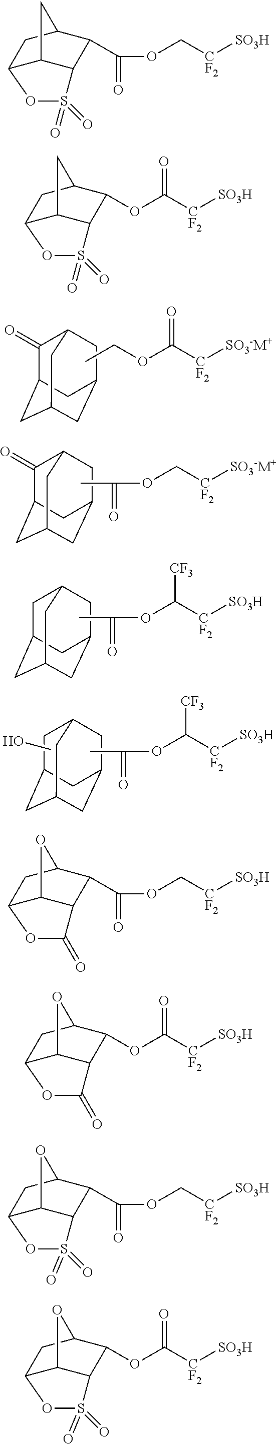

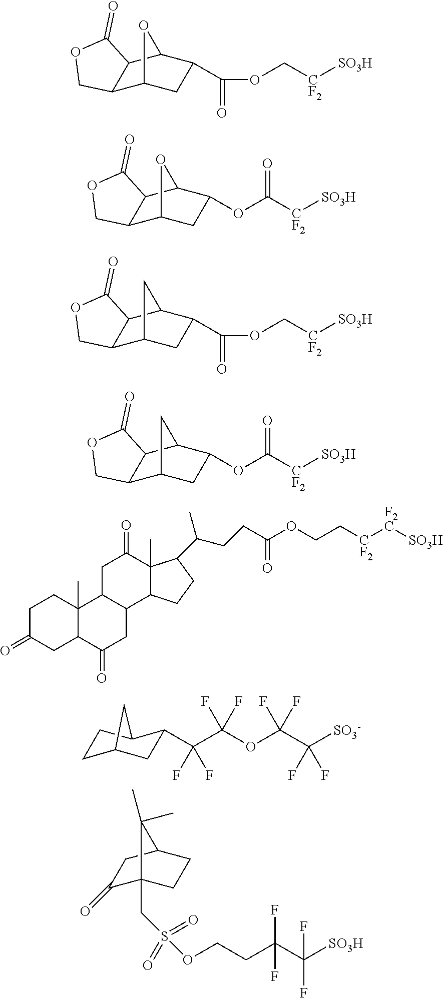

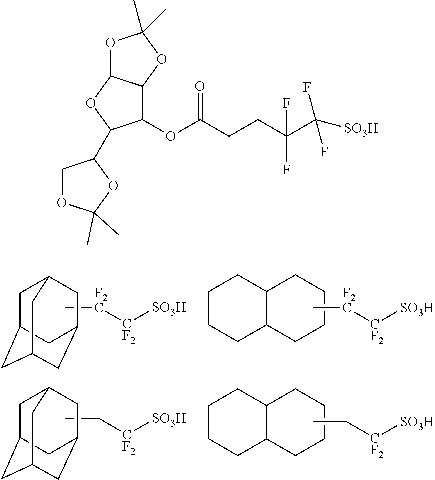

Suitable TAGs include those capable of generating a non-polymeric acid as described above. The TAG can be non-ionic or ionic. Suitable nonionic thermal acid generators include, for example, cyclohexyl trifluoromethyl sulfonate, methyl trifluoromethyl sulfonate, cyclohexyl p-toluenesulfonate, methyl p-toluenesulfonate, cyclohexyl 2,4,6-triisopropylbenzene sulfonate, nitrobenzyl esters, benzoin tosylate, 2-nitrobenzyl tosylate, tris(2,3-dibromopropyl)-1,3,5-triazine-2,4,6-trione, alkyl esters of organic sulfonic acids, p-toluenesulfonic acid, dodecylbenzenesulfonic acid, oxalic acid, phthalic acid, phosphoric acid, camphorsulfonic acid, 2,4,6-trimethylbenzene sulfonic acid, triisopropylnaphthalene sulfonic acid, 5-nitro-o-toluene sulfonic acid, 5-sulfosalicylic acid, 2,5-dimethylbenzene sulfonic acid, 2-nitrobenzene sulfonic acid, 3-chlorobenzene sulfonic acid, 3-bromobenzene sulfonic acid, 2-fluorocaprylnaphthalene sulfonic acid, dodecylbenzene sulfonic acid, 1-naphthol-5-sulfonic acid, 2-methoxy-4-hydroxy-5-benzoyl-benzene sulfonic acid, and their salts, and combinations thereof. Suitable ionic thermal acid generators include, for example, dodecylbenzenesulfonic acid triethylamine salts, dodecylbenzenedisulfonic acid triethylamine salts, p-toluene sulfonic acid-ammonium salts, p-toluene sulfonic acid-pyridinium salts, sulfonate salts, such as carbocyclic aryl and heteroaryl sulfonate salts, aliphatic sulfonate salts, and benzenesulfonate salts. Compounds that generate a sulfonic acid upon activation are generally suitable. Preferred thermal acid generators include p-toluenesulfonic acid ammonium salts, and heteroaryl sulfonate salts.

Preferably, the TAG is ionic with a reaction scheme for generation of a sulfonic acid as shown below:

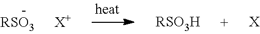

wherein RSO₃⁻ is the TAG anion and X⁺ is the TAG cation, preferably an organic cation. The cation can be a nitrogen-containing cation of the general formula (I):

(BH)⁺ (I)
which is the monoprotonated form of a nitrogen-containing base B. Suitable nitrogen-containing bases B include, for example: optionally substituted amines such as ammonia, difluoromethylammonia, C1-20 alkyl amines, and C3-30 aryl amines, for example, nitrogen-containing heteroaromatic bases such as pyridine or substituted pyridine (e.g., 3-fluoropyridine), pyrimidine and pyrazine; nitrogen-containing heterocyclic groups, for example, oxazole, oxazoline, or thiazoline. The foregoing nitrogen-containing bases B can be optionally substituted, for example, with one or more group chosen from alkyl, aryl, halogen atom (preferably fluorine), cyano, nitro and alkoxy. Of these, base B is preferably a heteroaromatic base.

Base B typically has a pKa from 0 to 5.0, or between 0 and 4.0, or between 0 and 3.0, or between 1.0 and 3.0. As used herein, the term “pKa” is used in accordance with its art-recognized meaning, that is, pKa is the negative log (to the base 10) of the dissociation constant of the conjugate acid (BH)⁺ of the basic moiety (B) in aqueous solution at about room temperature. In certain embodiments, base B has a boiling point less than about 170° C., or less than about 160° C., 150° C., 140° C., 130° C., 120° C., 110° C., 100° C. or 90° C.

Exemplary suitable nitrogen-containing cations (BH)⁺ include NH₄⁺, CF₂HNH₂⁺, CF₃CH₂NH₃⁺, (CH₃)₃NH⁺, (C₂H₅)₃NH⁺, (CH₃)₂(C₂H₅)NH⁺ and the following:

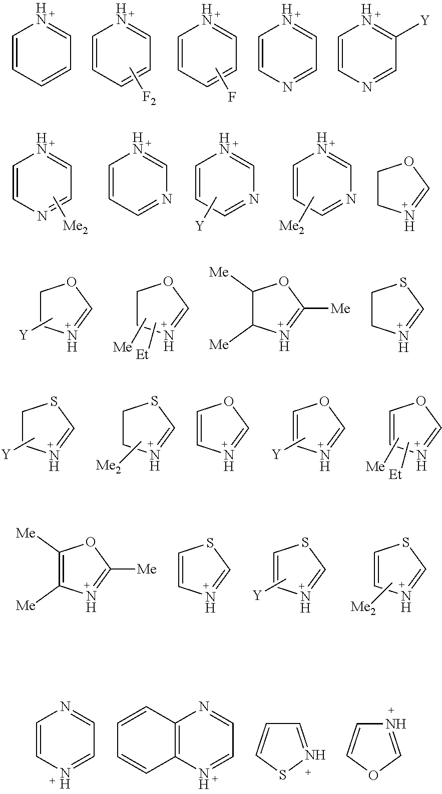

in which Y is alkyl, preferably, methyl or ethyl.

In particular embodiments, the solubility-shifting agent may be an acid such as trifluoromethanesulfonic acid, perfluoro-1-butanesulfonic acid, p-toluenesulfonic acid, 4-dodecylbenzenesulfonic acid, 2,4-dinitrobenzenesulfonic acid, and 2-trifluoromethylbenzenesulfonic acid; an acid generator such as triphenylsulfonium antimonate, pyridinium perfluorobutane sulfonate, 3-fluoropyridinium perfluorobutanesulfonate, 4-t-butylphenyltetramethylenesulfonium perfluoro-1-butane sulfonate, 4-t-butylphenyltetramethylenesulfonium 2-trifluoromethylbenzenesulfonate, and 4-t-butylphenyltetramethylenesulfonium 4,4,5,5,6,6-hexafluorodihydro-4H-1,3,2-dithiazine 1,1,3,3-tetraoxide; or a combination thereof. Exposure of the chemically amplified resist results in deprotection of the resist polymer in a layer adjacent to the spacer, rendering it soluble in a basic developer such as tetramethylammonium hydroxide (TMAH).

Alternatively, the first polymer fill may be processed like an NTD resist when the solubility-shifting agent includes a base or base generator. In this case, the first polymer fill is formulated to contain an acid or acid generator. The base from the solubility-shifting agent diffuses out of the spacer into the first polymer fill to quench the acid in a region adjacent to the spacer, thus enabling that region to be developed by an organic solvent such as NBA. In such embodiments, suitable solubility-shifting agents include, but are not limited to, hydroxides, carboxylates, amines, imines, amides, and mixtures thereof. Specific examples of bases include ammonium carbonate, ammonium hydroxide, ammonium hydrogen phosphate, ammonium phosphate, tetramethylammonium carbonate, tetramethylammonium hydroxide, tetramethylammonium hydrogen phosphate, tetramethylammonium phosphate, tetraethylammonium carbonate, tetraethylammonium hydroxide, tetraethylammonium hydrogen phosphate, tetraethylammonium phosphate, and combinations thereof. Amines include aliphatic amines, cycloaliphatic amines, aromatic amines and heterocyclic amines. The amine may be a primary, secondary or tertiary amine. The amine may be a monoamine, diamine or polyamine. Suitable amines may include C1-30 organic amines, imines, or amides, or may be a C1-30 quaternary ammonium salt of a strong base (e.g., a hydroxide or alkoxide) or a weak base (e.g., a carboxylate). Exemplary bases include amines such as tripropylamine, dodecylamine, tris(2-hydroxypropyl)amine, tetrakis(2-hydroxypropyl)ethylenediamine; aryl amines such as diphenylamine, triphenylamine, aminophenol, and 2-(4-aminophenyl)-2-(4-hydroxyphenyl)propane, Troger's base, a hindered amine such as diazabicycloundecene (DBU) or diazabicyclononene (DBN), amides like tert-butyl 1,3-dihydroxy-2-(hydroxymethyl)propan-2-ylcarbamate and tert-butyl 4-hydroxypiperidine-1-carboxylateor; or ionic quenchers including quaternary alkyl ammonium salts such as tetrabutylammonium hydroxide (TBAH) or tetrabutylammonium lactate. In another embodiment, the amine is a hydroxyamine. Examples of hydroxyamines include hydroxyamines having one or more hydroxyalkyl groups each having from 1 to about 8 carbon atoms, and preferably from 1 to about 5 carbon atoms such as hydroxymethyl, hydroxyethyl and hydroxybutyl groups. Specific examples of hydroxyamines include mono-, di- and tri-ethanolamine, 3-amino-1-propanol, 2-amino-2-methyl-1-propanol, 2-amino-2-ethyl-1,3-propanediol, tris(hydroxymethyl)aminomethane, N-methylethanolamine, 2-diethylamino-2-methyl-1-propanol and triethanolamine.

Suitable base generators may be thermal base generators. A thermal base generator forms a base upon heating above a first temperature, typically about 140° C. or higher. The thermal base generator may include a functional group such as an amide, sulfonamide, imide, imine, O-acyl oxime, benzoyloxycarbonyl derivative, quarternary ammonium salt, nifedipine, carbamate, and combinations thereof. Exemplary thermal base generators include o-{(.beta.-(dimethylamino)ethyl) aminocarbonyl}benzoic acid, o-{(.gamma.-(dimethylamino) propyl)aminocarbonyl}benzoic acid, 2,5-bis {(.beta.-(dimethylamino)ethyl)aminocarbonyl}terephthalic acid, 2,5-bis {(.gamma.-(dimethylamino) propyl)aminocarbonyl}terephthalic acid, 2,4-bis {(.beta.-(dimethylamino)ethyl)aminocarbonyl}isophthalic acid, 2,4-bis {(.gamma.-(dimethylamino) propyl)aminocarbonyl}isophthalic acid, and combinations thereof.

In one or more embodiments, the solubility-shifting agent includes a solvent. The solvent may be any suitable solvent that may facilitate deposition onto the carbon-containing spacers, provided that it does not dissolve the carbon-containing spacer. The solvent is typically chosen from water, organic solvents and mixtures thereof. In some embodiments, the solvent may include an organic-based solvent system comprising one or more organic solvents. The term “organic-based” means that the solvent system includes greater than 50 wt % organic solvent based on total solvents of the solubility-shifting agent composition, more typically greater than 90 wt %, greater than 95 wt %, greater than 99 wt % or 100 wt % organic solvents, based on total solvents of the solubility-shifting agent compositions. The solvent component is typically present in an amount of from 90 to 99 wt % based on the solubility-shifting agent composition.

Suitable organic solvents for the solubility-shifting agent composition include, for example: alkyl esters such as alkyl propionates such as n-butyl propionate, n-pentyl propionate, n-hexyl propionate and n-heptyl propionate, and alkyl butyrates such as n-butyl butyrate, isobutyl butyrate and isobutyl isobutyrate; ketones such as 2,5-dimethyl-4-hexanone and 2,6-dimethyl-4-heptanone; aliphatic hydrocarbons such as n-heptane, n-nonane, n-octane, n-decane, 2-methylheptane, 3-methylheptane, 3,3-dimethylhexane and 2,3,4-trimethylpentane, and fluorinated aliphatic hydrocarbons such as perfluoroheptane; alcohols such as straight, branched or cyclic C4-C9 monohydric alcohol such as 1-butanol, 2-butanol, isobutyl alcohol, tert-butyl alcohol, 3-methyl-1-butanol, 1-pentanol, 2-pentanol, 4-methyl-2-pentanol, 1-hexanol, 1-heptanol, 1-octanol, 2-hexanol, 2-heptanol, 2-octanol, 3-hexanol, 3-heptanol, 3-octanol and 4-octanol; 2,2,3,3,4,4-hexafluoro-1-butanol, 2,2,3,3,4,4,5,5-octafluoro-1-pentanol and 2,2,3,3,4,4,5,5,6,6-decafluoro-1-hexanol, and C5-C9 fluorinated diols such as 2,2,3,3,4,4-hexafluoro-1,5-pentanediol, 2,2,3,3,4,4,5,5-octafluoro-1,6-hexanediol and 2,2,3,3,4,4,5,5,6,6,7,7-dodecafluoro-1,8-octanediol; ethers such as isopentyl ether and dipropylene glycol monomethyl ether; and mixtures containing one or more of these solvents.

When the first resist is formed from a vinyl aromatic-based polymer, as is typical for KrF and EUV photoresists, and the resist is developed as a PTD resist, the solvent system preferably comprises one or more non-polar organic solvents. The term “non-polar organic-based” means that the solvent system includes greater than 50 wt % of combined non-polar organic solvents based on total solvents of the solubility-shifting agent composition, more typically greater than 70 wt %, greater than 85 wt % or 100 wt %, combined non-polar organic solvents, based on total solvents of the solubility-shifting agent composition. The non-polar organic solvents are typically present in the solvent system in a combined amount of from 70 to 98 wt %, preferably 80 to 95 wt %, more preferably from 85 to 98 wt %, based on the solvent system.

Suitable non-polar solvents include, for example, ethers, hydrocarbons, and combinations thereof, with ethers being preferred. Suitable ether solvents include, for example, alkyl monoethers and aromatic monoethers, particularly preferred of which are those having a total carbon number of from 6 to 16. Suitable alkyl monoethers include, for example, 1,4-cineole, 1,8-cineole, pinene oxide, di-n-propyl ether, diisopropyl ether, di-n-butyl ether, di-n-pentyl ether, diisoamyl ether, dihexyl ether, diheptyl ether, and dioctyl ether, with diisoamyl ether being preferred. Suitable aromatic monoethers include, for example, anisole, ethylbenzyl ether, diphenyl ether, dibenzyl ether and phenetole, with anisole being preferred. Suitable aliphatic hydrocarbons include, for example, n-heptane, 2-methylheptane, 3-methylheptane, 3,3-dimethylhexane, 2,3,4-trimethylpentane, n-octane, n-nonane, n-decane, and fluorinated compounds such as perfluoroheptane. Suitable aromatic hydrocarbons include, for example, benzene, toluene, and xylene.

In some embodiments, the solvent system further includes one or more alcohol and/or ester solvents. For certain compositions, an alcohol and/or ester solvent may provide enhanced solubility with respect to the solid components of the composition. Suitable alcohol solvents include, for example: straight, branched or cyclic C4 9 monohydric alcohol such as 1-butanol, 2-butanol, isobutyl alcohol, tert-butyl alcohol, 3-methyl-1-butanol, 1-pentanol, 2-pentanol, 4-methyl-2-pentanol, 1-hexanol, 1-heptanol, 1-octanol, 2-hexanol, 2-heptanol, 2-octanol, 3-hexanol, 3-heptanol, 3-octanol, 4-octanol, 2,2,3,3,4,4-hexafluoro-1-butanol, 2,2,3,3,4,4,5,5-octafluoro-1-pentanol, and 2,2,3,3,4,4,5,5,6,6-decafluoro-1-hexanol; and C5-9 fluorinated diols such as 2,2,3,3,4,4-hexafluoro-1,5-pentanediol, 2,2,3,3,4,4,5,5-octafluoro-1,6-hexanediol, and 2,2,3,3,4,4,5,5,6,6,7,7-dodecafluoro-1,8-octanediol. The alcohol solvent is preferably a C4-9 monohydric alcohol, with 4-methyl-2-pentanol being preferred. Suitable ester solvents include, for example, alkyl esters having a total carbon number of from 4 to 10, for example, alkyl propionates such as n-butyl propionate, n-pentyl propionate, n-hexyl propionate, and n-heptyl propionate, and alkyl butyrates such as n-butyl butyrate, isobutyl butyrate, and isobutyl isobutyrate. The one or more alcohol and/or ester solvents if used in the solvent system are typically present in a combined amount of from 2 to 50 wt %, more typically in an amount of from 2 to 30 wt %, based on the solvent system.

The solvent system can also include one or more additional solvents chosen, for example, from one or more of: ketones such as 2,5-dimethyl-4-hexanone and 2,6-dimethyl-4-heptanone; and polyethers such as dipropylene glycol monomethyl ether and tripropylene glycol monomethyl ether. Such additional solvents, if used, are typically present in a combined amount of from 1 to 20 wt % based on the solvent system.

When the first resist is formed from a vinyl aromatic-based polymer, a particularly preferred organic-based solvent system includes one or more monoether solvents in a combined amount of from 70 to 98 wt % based on the solvent system, and one or more alcohol and/or ester solvents in a combined amount of from 2 to 30 wt % based on the solvent system. The solvent system is typically present in the overcoat composition in an amount of from 90 to 99 wt %, preferably from 95 to 99 wt %, based on the overcoat composition.

In some embodiments, the solubility-shifting agent is coated over the carbon-containing spacer. To properly coat the carbon-containing spacer, the solubility-shifting agent may include a matrix polymer. The matrix polymer allows for the compositions to be coated over the resist pattern in the form of a layer having a desired thickness. This will help to ensure the presence of a sufficient content of the solubility-shifting agent for interaction with the spacer surface. Any matrix polymer commonly used in the art may be included in the solubility-shifting material. The matrix polymer should have good solubility in a solvent that does not dissolve the spacer. The matrix polymer can be chosen, for example, from polyvinyl alcohols, polyacrylic acids, polyvinyl pyrrolidones, polyvinyl amines, polyvinyl acetals, polystyrenes, poly(meth)acrylates and combinations thereof. Preferably, the polymer contains one or more functional group chosen from OH, —COOH, —SO3H, SiOH, hydroxyl styrene, hydroxyl naphthalene, sulfonamide, hexafluoroisopropyl alcohol, anhydrates, lactones, esters, ethers, allylamine, pyrrolidones and combinations thereof.

In some embodiments, the polymer contains one or more functional groups chosen, for example, from hydroxy, acid groups such as carboxyl, sulfonic acid and sulfonamide, silanol, fluoroalcohol such as hexafluoroisopropyl alcohol [—C(CF3)2OH], anhydrates, lactones, esters, ethers, allylamine, pyrrolidones and combinations thereof. The polymer can be a homopolymer or a copolymer having a plurality of distinct repeat units, for example, two, three, four or more distinct repeat units. In one aspect, the repeat units of the polymer are all formed from (meth)acrylate monomers, are all formed from (vinyl)aromatic monomers or are all formed from (meth)acrylate monomers and (vinyl)aromatic monomers. When the polymer includes more than one type of repeat unit, it typically takes the form of a random copolymer.

In particular embodiments, the matrix polymer may be a t-butyl acrylate (TBA)/p-hydroxystyrene (PHS) copolymer, a butyl acrylate (BA)/PHS copolymer, a TBA/methacrylic acid (MAA) copolymer, a BA/MAA copolymer, a PHS/methacrylate (MA) copolymer, and combinations thereof.

The solubility-shifting agent compositions typically include a single polymer but can optionally include one or more additional polymers. The content of the polymer in the composition will depend, for example, on the target thickness of the layer, with a higher polymer content being used when thicker layer is desired. The polymer is typically present in the pattern solubility-shifting agent composition in an amount of from 80 to 99.9 wt %, more typically from 90 to 99 wt %, or 95 to 99 wt %, based on total solids of the solubility-shifting agent composition. The weight average molecular weight (Mw) of the polymer is typically less than 400,000, preferably from 3000 to 50,000, more preferably from 3000 to 25,000, as measured by GPC versus polystyrene standards. Typically, the polymer will have a polydispersity index (PDI=Mw/Mn) of 3 or less, preferably 2 or less, as measured by GPC versus polystyrene standards.

Suitable polymers for use in the solubility-shifting agent compositions are commercially available and/or can readily be made by persons skilled in the art. For example, the polymer may be synthesized by dissolving selected monomers corresponding to units of the polymer in an organic solvent, adding a radical polymerization initiator thereto, and effecting heat polymerization to form the polymer. Examples of suitable organic solvents that can be used for polymerization of the polymer include, for example, toluene, benzene, tetrahydrofuran, diethyl ether, dioxane, ethyl lactate and methyl isobutyl carbinol. Suitable polymerization initiators include, for example, 2,2′-azobisisobutyronitrile (AIBN), 2,2′-azobis(2,4-dimethylvaleronitrile), dimethyl 2,2-azobis(2-methylpropionate), benzoyl peroxide and lauroyl peroxide.

Solubility-shifting agents including a matrix polymer may be coated over the carbon-containing spacer according to methods known in the art. Typically, a solubility-shifting agent that includes a matrix polymer may coated over the carbon-containing spacers by spin coating. The solids content of the solubility-agent may be tailored to provide a film of a desired thickness of the solubility-shifting agent over the carbon-containing spacers. For example, the solids content of the solubility-shifting agent solution may be adjusted to provide a desired film thickness based upon the specific coating equipment utilized, the viscosity of the solution, the speed of the coating tool and the amount of time allowed for spinning. A typical thickness for the solubility-shifting agent is from about 200 Å to about 1500 Å.

In one or more embodiments, a solubility-shifting agent includes an active material (i.e., and acid, acid generator, base or base generator), a solvent, and a matrix polymer as previously described. A typical formulation for such solubility-shifting agent may include about 1 wt % to about 10 wt % solids and about 90 wt % to about 99 wt % solvent, based on the total weight of the solubility shifting agent, where the solids include the active material and the matrix polymer. Within the solids content, the active material may be included in an amount ranging from about 0.1 wt % to about 10 wt %.

The solubility-shifting agent may include additives having various purposes, depending on the particular chemistry being used. In some embodiments, a surfactant may be included in the solubility-shifting agent. A surfactant may be included in the solubility-shifting agent to help with coating quality, especially when needing to fill thin gaps between the carbon-containing spacers. Any suitable surfactant known in the art may be included in the solubility-shifting agent.

As noted above, in one or more embodiments, the solubility-shifting agent is absorbed into the carbon-containing spacers. Absorption of the solubility-shifting agent into the carbon-containing spacers may be achieved by performing a thermal pretreatment such as a bake. The bake may be a soft bake. The temperature and time of the soft bake may depend on the composition of the carbon-containing spacers, and the desired amount of diffusion of the solubility-shifting agent into the carbon-containing spacers. Typically, a soft bake may be performed for about 30 to about 90 seconds at a temperature ranging from about 50° C. to about 150° C.

After absorption into the carbon-containing spacers, a coating may remain on the carbon-containing spacers. In one or more embodiments, the coating layer may be removed by a rinse. The rinse may be accomplished by rinsing the coated substrate with a solvent that dissolves the coating layer but does not dissolve the resistcarbon-containing spacers. The rinse may be carried out using any suitable method, for example, by dipping a substrate in a bath filled with the solvent for a fixed time (dip method), by raising the solvent on a substrate surface by the effect of a surface tension and keeping it still for a fixed time, thereby dissolving the coating layer (puddle method), by spraying the solvent on a substrate surface (spray method), or by continuously ejecting the solvent on a substrate rotating at a constant speed while scanning the solvent ejecting nozzle at a constant rate (dynamic dispense method).

At block 210 of method 200, a first polymer fill is deposited on the substrate. A coated substrate layered with carbon-containing spacers 306, a solubility-shifting agent 308, and a first polymer fill 310 is shown in FIG. 3E. The first polymer fill may be deposited on the substrate such that it fills gaps between the carbon-containing spacers and is in contact with the carbon-containing spacers or the solubility-shifting agent. In one or more embodiments, the first polymer fill completely covers the substrate, the carbon-containing spacers, and the solubility-shifting agent. The first polymer fill may be deposited on the substrate according to any suitable method known in the art such as, for example, spin-on deposition or vapor-phase treatment.

In one or more embodiments, the first polymer fill comprises a chemically-amplified composition the includes a polymer having acid-labile groups of which solubility in an alkali developer increases and solubility in an organic solvent decreases under the action of an acid. Suitable acid-soluble and a solvent. Suitable polymers having acid-labile groups are commonly used in resist compositions and are well known in the art. Preferably, the polymers are formed from monomers chosen from vinyl aromatic (e.g., styrene and hydroxystyrene), (meth)acrylate, norbornene, and combinations thereof. In a preferred aspect, the polymer is vinyl aromatic-based, wherein more than 50 mole % of the polymerized units in the polymer, typically more than 80 mole % of the polymerized units in the polymer, are formed from vinyl aromatic monomers. In other embodiments, the polymers may be made from monomers including p-hydroxystryene, styrene, t-butyl acrylate, and combinations thereof. In particular embodiments, the polymer is made from all three of p-hydroxystyrene, styrene, and t-butylacrylate. Such polymer may be prepared from a polymerization reaction including from about 50 to 80% p-hydroxystyrene, from about 10% to about 30% styrene, and from about 10% to about 30% t-butylacrylate. For example, a polymerization reaction to produce a polymer included in the second resist may include p-hdroxystyrene in an amount ranging from a lower limit of one of about 50%, about 55%, about 60%, and about 65% to an upper limit of one of about 65%, about 70%, about 75%, and about 80%, where any lower limit may be paired with any mathematically compatible upper limit, and styrene and t-butyl acrylate in individual amounts ranging from a lower limit of one of about 10%, about 12%, about 14%, about 16%, about 18%, and about 20% to an upper limit of one of about 20%, about 22%, about 24%, about 26%, about 28%, and about 30%, where any lower limit may be paired with any mathematically compatible upper limit.

The polymer included in the first polymer fill may have a weight average molecular weight (Mw) ranging from about 1 kg/mol to about 100 kg/mol. For example, in one or more embodiments, the first polymer fill may include a polymer having a Mw ranging from a lower limit of one of about 1 kg/mol, about 2 kg/mol, about 5 kg/mol, about 10 kg/mol, about 15 kg/mol, about 20 kg/mol, and about 25 kg/mol to an upper limit of one of about 25 kg/mol, about 50 kg/mol, about 75 kg/mol, about 80 kg/mol, about 90 kg/mol, and about 100 kg/mol, where any lower limit may be paired with any mathematically compatible upper limit. A polymer having such Mw may exhibit desired solubility characteristics, such as, in particular, the dissolution rate.

In one or more embodiments, the first polymer fill includes a solvent. The solvent may be as previously described with respect to the solvent included in the solubility-shifting agent. In particular embodiments, the solvent in the first polymer fill is the same as the solvent in the solubility-shifting agent.

In embodiments when the solubility-shifting agent includes a base or base generator and where the first polymer may be processed like an NTD resist, the first polymer fill includes an acid and/or acid generator. The acid or acid generator may be as previously described with respect to the acid or acid generator included in the solubility-shifting agent. Protected functional groups in the second resist may be deprotected via an acid catalyzed reaction, which may be facilitated by the inclusion of an acid or acid generator in the second resist.

The first polymer fill may include additives having various purposes, depending on the particular chemistry being used. In some embodiments, a quencher is included in the first polymer fill. A quencher may be included in the first polymer fill to help control the diffusion of the active material in the solubility-shifting agent. Suitable quenchers include any of the bases previously listed with reference to the solubility-shifting material.

In method 200, at block 212, the solubility-shifting agent is diffused into the first polymer fill from the carbon-containing spacer. In one or more embodiments, diffusion of the solubility-shifting agent into the first polymer fill is achieved by performing a bake. The bake may be carried out with a hotplate or oven. The temperature and time of the bake may depend on the identity of the second resist, and the desired amount of diffusion of the solubility-shifting agent into the second resist. Suitable conditions for the bake may include a temperature ranging from about 50° C. to about 160° C., and a time ranging from about 30 seconds to about 90 seconds.

In one or more embodiments, after the bake, a solubility-shifted region may be present around the edges of the first polymer fill. The amount of diffusion of the solubility-shifting agent may correspond to the thickness of the solubility-shifted region. In some embodiments, the solubility-shifted region extends into the first polymer fill such that it has a thickness of about 5 nm to about 60 nm. For example, the thickness of the solubility-shifted region may range from a lower limit of one of about 5 nm, about 10 nm, about 15 nm, about 20 nm, and about 25 nm to an upper limit of one of about 40 nm, about 45 nm, about 50 nm, about 55 nm, and about 60 nm, where any lower limit may be paired with any mathematically compatible upper limit. In one or more embodiments, the thickness of the solubility-shifted region may correspond to the desired width of a line of a pattern that is to be cut into the substrate.

A coated substrate including a solubility-shifted region is shown in FIG. 3F. As shown in FIG. 3F, the coated substrate includes a substrate layer 302. The substrate is as previously described. The carbon-containing spacers 306, include an amount of absorbed solubility-shifting agent 308. The first polymer fill 310 is coated over the carbon-containing spacers and the substrate. In one or more embodiments, the first polymer fill 310 completely covers the substrate 302 and the carbon-containing spacers 306. A solubility-shifted region 312 of the second resist is shown bordering the carbon-containing spacers.

The solubility-shifted region may have a different solubility than the region of the first polymer fill that was not exposed to the solubility-shifting agent. As such, the solubility-shifted region and the unexposed region of the first polymer fill may be soluble in different resist developers.

Finally, at block 214 of method 200, the deposited layer of first polymer fill may be developed using a specific developer such that the unexposed region of the second resist remains. In one or more embodiments, the solubility-shifted region of the first polymer fill is developed by first being exposed to actinic radiation, and then being exposed to a specific developer. In other embodiments, the solubility-shifted region of the first polymer fill is only exposed to the specific developer. The specific developer may depend on the tone of the first polymer fill. For example, if the solubility-shifting agent includes an acid or acid generator, the specific developer may be a base such as tetramethylammonium hydroxide. On the other hand, if the solubility-shifting agent includes a base or base generator, the specific developer may be an organic solvent, such as n-butyl acetate or 2-heptanone.

As described previously, the thickness of the solubility-shifted region may correspond to the desired width of a line of a pattern to be cut into the substrate. FIG. 3G shows a coated substrate that has been developed according to embodiments of the present disclosure. In one or more embodiments, the first polymer fill 310 is developed so as to dissolve the solubility-shifted region, which is between the carbon-containing spacers and the first polymer fill. Accordingly, dissolution of the solubility-shifted region may result in the formation of trenches 314 between the carbon-containing spacers 306 and the first polymer fill 310 in which the substrate 302 is exposed.

Method 200 may provide known spaces at a pitch 4× improved from the initial pitch. The precise width of the trenches (e.g., anti-spacers) formed may be set by a particular method used. In one or more embodiments, the pitch starts at a value set by the lithography, is doubled with the spacer, and then is doubled again.

Method 200 represents one possible embodiment and is not intended to limit the scope of the present invention. As will be appreciated by one of ordinary skill in the art, the present invention may encompass various alternative methods, such as, for example, methods in which the solubility-shifting agent is diffused into the carbon-containing spacers rather than the first polymer fill. In such alternate embodiments, the components and techniques used in the methods may be as previously described with reference to method 200.

As mentioned above, in one or more embodiments, the solubility-shifting agent is diffused into the carbon-containing spacers. In such embodiments, a method may include initially forming the carbon-containing spacers and then coating the carbon-containing spacers with a solubility-shifting agent. At this point, the solubility-shifting agent may be diffused into the carbon-containing spacers a predetermined distance to provide a solubility-shifted region of the carbon-containing spacers. While diffusion of the solubility-shifting agent may occur at a different point in such method and into a different component, diffusion of the solubility-shifting agent may be carried out as descried above in method 200. After the solubility-shifting agent is diffused into the carbon-containing spacers, the first polymer fill may be deposited on the substrate. Then, the substrate may be developed and etched as described with reference to method 200, where the solubility-shifted region of the carbon-containing spacers is soluble in the specific developer.

Although method 200 includes providing a first relief pattern on a substrate and then forming carbon-containing sidewalls on the first relief pattern, alternate methods may include first providing a first relief pattern on a substrate layered with amorphous carbon, applying an inorganic spacer to the first relief pattern, and subsequently etching the pattern defined by the inorganic spacer and the first relief pattern into the underlying layer of amorphous carbon. Suitable inorganic spacers include low temperature oxides as are known in the art. Such methods may then proceed as discussed in method 200.

Although only a few example embodiments have been described in detail above, those skilled in the art will readily appreciate that many modifications are possible in the example embodiments without materially departing from this invention. Accordingly, all such modifications are intended to be included within the scope of this disclosure as defined in the following claims.

1. A method of microfabrication comprising:
providing a first relief pattern on a substrate, wherein the first relief pattern comprises a first resist;
forming carbon-containing sidewall spacers on the first relief pattern;
removing the first relief pattern;
coating the carbon-containing sidewall spacers with a solubility-shifting agent;
depositing a first polymer fill on the carbon-containing sidewall spacers such that the first polymer fill is in contact with the carbon-containing sidewall spacers;
diffusing the solubility-shifting agent a predetermined distance into the first polymer fill to provide a solubility-shifted region of the first polymer fill, wherein the solubility-shifted region of the first polymer fill borders the carbon-containing sidewall spacers; and
developing the first polymer fill such that the solubility-shifted region is dissolved providing trenches between the carbon-containing sidewall spacers and the first polymer fill where a portion of the substrate is exposed.

2. The method of claim 1, wherein the carbon-containing sidewall spacers comprise amorphous carbon, a hydrogenated amorphous carbon, or an amorphous carbon formed from partially or completely doped derivatives of hydrocarbon compounds, including nitrogen-, fluorine-, oxygen-, hydroxyl group, and boron-containing derivatives of hydrocarbon compounds.

3. A method of microfabrication comprising:
providing a layer of amorphous carbon on a substrate;
providing a first relief pattern on the layer of amorphous carbon, wherein the first relief pattern comprises a first resist;
applying an inorganic spacer to the first relief pattern;
transferring a pattern defined by the first relief pattern and the inorganic spacer into the layer of amorphous carbon to provide an etched layer of amorphous carbon;
removing the first relief pattern and the inorganic spacer;
coating the etched layer of amorphous carbon with a solubility-shifting agent;
depositing a first polymer fill on the etched layer of amorphous carbon;
diffusing the solubility-shifting agent a predetermined distance into the first polymer fill to provide a solubility-shifted region of the first polymer fill, wherein the solubility-shifted region of the first polymer fill borders the etched layer of amorphous carbon; and
developing the first polymer fill such that the solubility-shifted region is dissolved providing trenches between the etched layer of amorphous carbon and the first polymer fill where a portion of the substrate is exposed.

4. The method of claim 1, wherein the carbon-containing sidewall spacers have a pitch of 8× and a critical dimension of 3× in relation to a final target critical dimension width of x.

5. The method of claim 1, wherein removing the first relief pattern comprises treating the pattern with a wet stripping process.

6. The method of claim 1, wherein the first polymer fill comprises a polymer comprising monomeric units selected from the group consisting of acrylate, methacrylate, p-hydroxystyrene, styrene, norbornene and combinations thereof.

7. The method of claim 1, wherein the solubility-shifting agent comprises an acid generator.

8. The method of claim 7, wherein the acid generator is free of fluorine.

9. The method of claim 7, wherein the acid generator is selected from the group consisting of triphenylsulfonium antimonate pyridinium perfluorobutane sulfonate, 3-fluoropyridinium perfluorobutanesulfonate, 4-t-butylphenyltetramethylenesulfonium perfluoro-1-butanesulfonate, 4-t-butylphenyltetramethylenesulfonium 2-trifluoromethylbenzenesulfonate, 4-t-butylphenyltetramethylenesulfonium 4,4,5,5,6,6-hexafluorodihydro-4H-1,3,2-dithiazine 1,1,3,3-tetraoxide, and combinations thereof.

10. The method of claim 1, wherein the solubility-shifting agent comprises an acid.

11. The method of claim 10, wherein the acid is free of fluorine.

12. The method of claim 10, wherein the acid is selected from the group consisting of trifluoromethanesulfonic acid, perfluoro-1-butanesulfonic acid, p-toluenesulfonic acid, 4-dodecylbenzenesulfonic acid, 2,4-dinitrobenzenesulfonic acid, 2-trifluoromethylbenzenesulfonic acid, and combinations thereof.

13. The method of claim 1, wherein the solubility-shifting agent comprises a matrix polymer comprising monomers selected from the group consisting of monomers with ethylenically unsaturated polymerizable double bonds, (meth)acrylate monomers, (meth)acrylic acids, vinyl aromatic monomers styrene, hydroxystyrene, vinyl naphthalene, acenaphthylene, vinyl alcohol, vinyl chloride, vinyl pyrrolidone, vinyl pyridine vinyl acetal, maleic anhydride, maleimides, norbornenes, and combinations thereof.

14. The method of claim 1, wherein the solubility-shifting agent comprises a matrix polymer comprising monomers comprising one or more functional groups chosen from hydroxy, carboxyl, sulfonic acid, sulfonamide, silanol, fluoroalcohol, anhydrates, lactones, esters, ethers, allylamine, pyrrolidones, and combinations thereof.

15. The method of claim 1, further comprising, directly after coating the carbon-containing spacers with the solubility-shifting agent, diffusing the solubility-shifting agent into the carbon-containing spacers.

16. The method of claim 16, wherein diffusing the solubility-shifting agent into the first relief pattern is achieved by performing a bake.

17. The method of claim 1, wherein a final pattern has 4 times the number of features as the first relief pattern.
